(19) United States
(12) Patent Application Publication
(10) Pub. No.: US 2007/0269977 A1
(43) Pub. Date: Nov. 22, 2007

(54) Method of forming a multilayer wiring by the use of copper damascene technique

(75) Inventors: Shinichi Chikaki, Tokyo (JP); Ryotaro Yagi, Kyoto (JP); Yoshinori Shishida, Gifu (JP); Hirofumi Tanaka, Chiba (JP); Takahiro Nakayama, Ibaraki (JP); Yoko Uchida, Tokyo (JP)

Correspondence Address: YOUNG & THOMPSON, 745 SOUTH 23RD STREET, 2ND FLOOR, ARLINGTON, VA, 22202, US

(73) Assignees: NEC CORPORATION, TOKYO (JP); ROHM CO., LTD, KYOTO (JP); SANYO ELECTRONIC CO., OSAKA (JP); ULVAC, INC, CHIGASAKI-SHI (JP); RENESAS TECHNOLOGY CORP, TOKYO (JP)

(21) Appl. No.: 11/798,684

(22) Filed: May 16, 2007

(30) Foreign Application Priority Data
May 16, 2006 (JP) 2006-136072

(51) Int. Cl. H01L 21/4763

(52) U.S. Cl. 438/640; 438/638

(57) ABSTRACT

In a formation method of a copper damascene multilayer wiring in a semiconductor integrated circuit device, after performing an oxidation process on a surface of copper, a heating process of 300° C. to 400° C. is performed in a reducing gas atmosphere, or a plasma annealing process is performed in a reducing gas plasma atmosphere.

This application is based upon and claims the benefit of priority from Japanese patent application No. 2006-136072, filed on May 16, 2006, the disclosure of which is incorporated herein in its entirety by reference.

### BACKGROUND OF THE INVENTION

1. Field of the Invention

The present invention relates to a formation method of a copper damascene multilayer wiring in a semiconductor integrated circuit device.

2. Description of the Related Art

As the related art of the formation technology of wiring which forms a semiconductor integrated circuit device, for example, a method of depositing a conductive film such as aluminum on an insulating film and then patterning the film by a general photolithography technique and dry etching technique has been established.

However, in the above-wiring formation technology, miniaturization of elements or wirings which form a semiconductor integrated circuit device causes a significant increase of the resistance of wiring to thereby produce a wiring delay. As a result, limitations are being put on improvement of the performance of a semiconductor integrated circuit device.

In particular, since aluminum has a high resistivity, it is desirable to use copper, which has a low resistivity, as a wiring material. However, copper cannot be patterned by dry etching.

Accordingly, wiring formation technology called damascene technique has been examined in recent years. The damascene technique is a method of forming electrodes or wirings by filling. In the damascene technique, wiring grooves and contact holes for wiring formation are first formed on an insulating film such as an interlayer insulating film of a semiconductor substrate, and a copper thin film is deposited thereon by a plating method. Then, an upper portion of the insulating film is polished so as to remove the copper thin film formed on the insulating film by a chemical mechanical polishing (CMP) method. By removing the copper thin film formed on the insulating film, wiring is formed in such a state that the wiring grooves and the contact holes have been filled with copper. An annealing process is performed after the copper thin film is deposited by the plating method. The annealing process of copper is used for various purposes or effects in the formation of the damascene wiring.

For example, Japanese laid-open patent publication No. 2004-79835 discloses improvement of the reliability of wiring. Furthermore, Japanese laid-open patent publication No. 11-340318 discloses that good filling characteristics can be obtained in a case where a high-pressure reflow or the like is used. Moreover, Japanese laid-open patent publication No. 8-264535 discloses a method of depositing copper in wiring grooves by the use of an existing sputtering apparatus and heat treatment apparatus and without need of a special-purpose integrated apparatus.

### SUMMARY OF THE INVENTION

An exemplary object of the present invention is to provide a formation method of a copper damascene multilayer wiring which can achieve both of control of shape changes of copper and improvement of electric characteristics by performing an annealing process.

According to an exemplary aspect of the present invention, in a formation method of a copper damascene multilayer wiring in a semiconductor integrated circuit device, after performing an oxidation process on a surface of copper, a heating process of 300° C. to 400° C. is performed in a reducing gas atmosphere, or a plasma annealing process is performed in a reducing gas plasma atmosphere.

### BRIEF DESCRIPTION OF THE DRAWINGS

FIGS. 1A to 1D are cross-sectional views explanatory of a formation method of a copper damascene multilayer wiring according to a first exemplary embodiment of the present invention; and

FIGS. 2A to 2D are cross-sectional views explanatory of a formation method of a copper damascene multilayer wiring according to a second exemplary embodiment of the present invention.

### DETAILED DESCRIPTION OF THE INVENTION

One example of an oxidation process on a surface of copper according to the present invention includes performing an exposure process for a predetermined period of time by using an atmosphere environment, an oxidizing furnace, an oxidizing chemical liquid bath, or an oxidizing plasma chamber that is controlled in concentration of an oxidizing agent and temperature in order to form an oxide film having a constant film thickness and film quality.

Furthermore, a reducing furnace or a reducing plasma chamber capable of exposing to an activated reducing gas at a relatively high temperature is used in order to achieve an effective reducing process.

For example, after the oxidation process on the surface of the copper, a heating process of 300° C. to 400° C. is performed in a reducing gas atmosphere, or a plasma annealing process is performed in a reducing gas plasma atmosphere.

Examples of the oxidation process on the surface of the copper include the following methods.

(1) Heat treatment at 200° C. to 500° C. in a nitrogen gas atmosphere containing 0.1% to 20% oxygen.

(2) Immersion in a solution containing hydrogen peroxide as the oxidation process on the surface of the copper.

(3) Immersion in water in which an ozone gas is dissolved.

(4) Exposure to an atmosphere containing 1 PPM to 100 PPM ozone gas or 1% to 100% oxygen gas at the room temperature for at least 3 hours.

(5) Exposure to a gas plasma atmosphere containing an oxygen gas.

Furthermore, examples of the reducing gas include (1) tetramethylcyclotetrasiloxane vapor, (2) hexamethyldisilazan vapor, and (3) hexamethyldisiloxane vapor.

### First Exemplary Embodiment

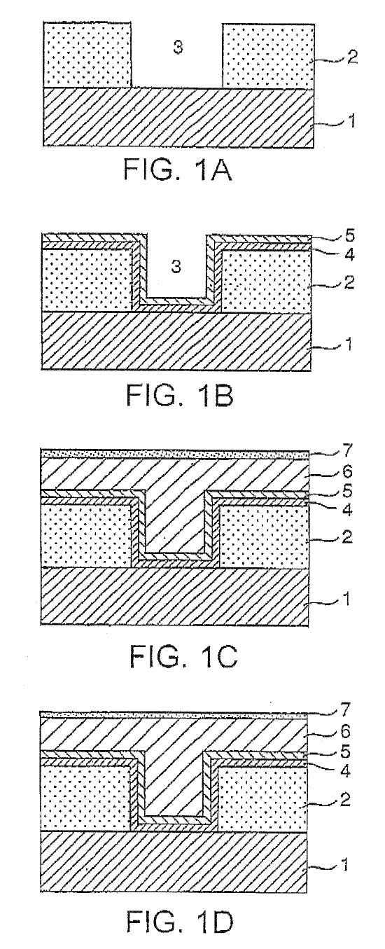

A formation method of a copper damascene multilayer wiring according to a first exemplary embodiment of the present invention will be described with reference to FIGS. 1A to 1D.

First, a groove pattern 3 is formed in an interlayer insulating film 2 formed on a substrate 1 (see FIG. 1A).

Then, a barrier metal film 4 is formed on the overall surface of the interlayer insulating film 2 by a sputtering method, and a copper seed film 5 is formed thereon by a sputtering method. Here, the barrier metal film 4 is a metal film made of, for example, tantalum, titanium, or the like and has a function of preventing diffusion of copper into the interlayer insulating film 2. Furthermore, the copper seed film 5 has a function of a feeding film in an electrolytic copper plating process upon forming a copper plating film 6, which will be described later. Additionally, the copper seed film 5 also has a function of improving adhesion of the copper plating film 6 and the barrier metal film 4 (see FIG. 1B).

Next, copper is filled into the groove pattern 3 by a copper plating method. In this manner, the copper plating film 6 is formed. Thereafter, the substrate is exposed to an atmosphere that is controlled at a temperature of 25° C. and a humidity of 10% to 50% for 24 hours. As a result, a copper oxide film 7 is formed on the copper plating film 6 (see FIG. 1C).

Finally, the substrate is exposed to an atmosphere in which TMCTS (tetramethylcyclotetrasiloxane) vapor is added to a nitrogen gas carrier having a temperature of 400° C. in a tube-type annealing furnace (not shown) for 60 minutes. Thus, a layer resistance of copper can be reduced while roughness of a surface of the copper plating film 6 is suppressed. In this manner, a copper damascene multilayer wiring according to the first embodiment of the present invention is formed (see FIG. 1D).

### Second Exemplary Embodiment

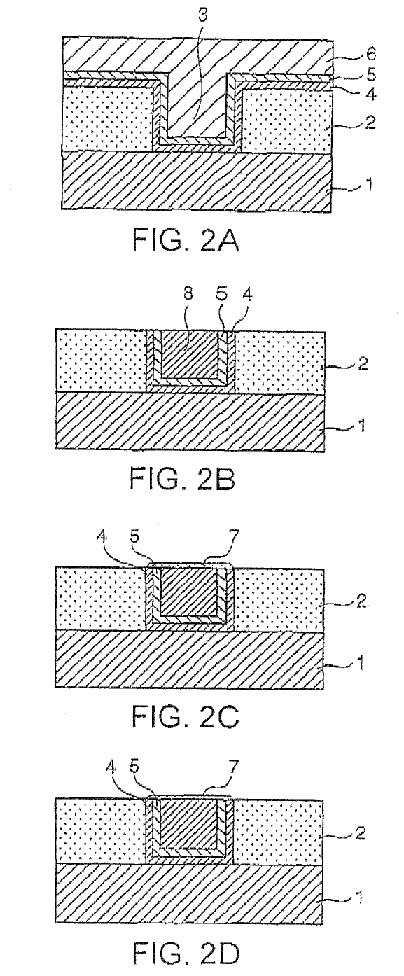

A formation method of a copper damascene multilayer wiring according to a second exemplary embodiment of the present invention will be described with reference to FIGS. 2A to 2D.

First, a groove pattern 3 is formed in an interlayer insulating film 2 formed on a substrate 1. Then, a barrier metal film 4 is formed on the overall surface of the interlayer dielectric 2 by a sputtering method, and a copper seed film 5 is formed thereon by a sputtering method. Here, the barrier metal film 4 is a metal film made of, for example, tantalum, titanium, or the like and has a function of preventing diffusion of copper into the interlayer insulating film 2. Furthermore, the copper seed film 5 has a function of a feeding film in an electrolytic copper plating process upon forming a copper plating film 6. Additionally, the copper seed film 5 also has a function of improving adhesion of the copper plating film 6, which will be described later, and the barrier metal film 4.

Next, the barrier metal film 4, the copper seed film 5, and the copper plating film 6 formed on the interlayer insulating film 2 are removed by a CMP method. In this manner, a damascene copper wiring 8 as a fine copper wiring is formed in the groove pattern 3 (see FIG. 2B).

Subsequently, the substrate 1 is immersed in a hydrogen peroxide solution of 5 weight % to 50 weight % for one minute. As a result, a copper oxide film 7 is formed on the damascene copper wiring 8 (see FIG. 2C).

Finally, TMCTS (tetramethylcyclotetrasiloxane) vapor is added to a nitrogen atmosphere having a temperature of 400° C., to which the substrate 1 is exposed for 60 minutes. As a consequence, it is possible to reduce a resistance of the damascene copper wiring 8 (fine copper wiring) without cohesion of copper. In this manner, a copper damascene multilayer wiring according to the second embodiment of the present invention is formed (see FIG. 2D).

### Other Exemplary Embodiments

In a third exemplary embodiment, the oxidation process of the surface of the copper includes heat treatment at 200° C. to 500° C. in a nitrogen gas atmosphere containing 0.1% to 20% oxygen.

In a fourth exemplary embodiment, the oxidation process of the surface of the copper includes immersion in a solution containing hydrogen peroxide.

In a fifth exemplary embodiment, the oxidation process of the surface of the copper includes immersion in water in which an ozone gas is dissolved.

In a sixth exemplary embodiment, the oxidation process of the surface of the copper includes exposure to an atmosphere containing 1 PPM to 100 PPM ozone gas or 1% to 100% oxygen gas at the room temperature for at least 3 hours.

In a seventh exemplary embodiment, the oxidation process of the surface of the copper includes exposure to a gas plasma atmosphere containing an oxygen gas.

In an eighth exemplary embodiment, for example, tetramethylcyclotetrasiloxane vapor, hexamethyldisilazan vapor, or hexamethyldisiloxane vapor is used as the reducing gas.

According to the present invention, for example, it is possible to achieve an effect that formation of a copper wiring having excellent electric characteristics and less shape variations is facilitated.

As described above, according to exemplary embodiments of the present invention, an annealing process using a reducing gas is performed subsequently to an oxidation process on a surface of copper. Although the present invention has been shown and described, particularly, with reference to the exemplary embodiments, the present invention is not limited to those embodiments. It should be understood by those skilled in the art that various changes in the form and details may be made therein without departing from the spirit and scope of the present invention defined by the appended claims.

What is claimed is:

1. A formation method of a copper damascene multilayer wiring in a semiconductor integrated circuit device, comprising:
performing an oxidation process on a surface of copper; and
thereafter performing a heating process of 300° C. to 400° C. in a reducing gas atmosphere or performing a plasma annealing process in a reducing gas plasma atmosphere.

2. The formation method of a copper damascene multilayer wiring according to claim 1, wherein:
the oxidation process on the surface of the copper comprises heat treatment at 200° C. to 500° C. in a nitrogen gas atmosphere containing 0.1% to 20% oxygen.

3. The formation method of a copper damascene multilayer wiring according to claim 1, wherein:
the oxidation process on the surface of the copper comprises immersion in a solution containing hydrogen peroxide.

4. The formation method of a copper damascene multilayer wiring according claim 1, wherein:
the oxidation process on the surface of the copper comprises immersion in water in which an ozone gas is dissolved.

5. The formation method of a copper damascene multilayer wiring according to claim 1, wherein:
the oxidation process on the surface of the copper comprises exposure to an atmosphere containing 1 PPM to 100 PPM ozone gas or 1% to 100% oxygen gas at a room temperature for at least 3 hours.

6. The formation method of a copper damascene multilayer wiring according to claim 1, wherein:
the oxidation process on the surface of the copper comprises exposure to a gas plasma atmosphere containing an oxygen gas.

7. The formation method of a copper damascene multilayer wiring according to claim 1, wherein:
tetramethylcyclotetrasiloxane vapor is used as the reducing gas.

8. The formation method of a copper damascene multilayer wiring according to claim 1, wherein:
hexamethyldisilazan vapor is used as the reducing gas.

9. The formation method of a copper damascene multilayer wiring according to claim 1, wherein:
hexamethyldisiloxane vapor is used as the reducing gas.
